(19) United States
(12) Patent Application Publication
(10) Pub. No.: US 2026/0082907 A1
(43) Pub. Date: Mar. 19, 2026

(54) Power Semiconductor Device Assembly

(71) Applicant: Wolfspeed, Inc., Durham, NC (US)

(72) Inventors: Bakhtiyar Mohammad Nafis, Springdale, AR (US); Benjamin Allen Samples, Fayetteville, AR (US); Sayan Seal, Fayetteville, AR (US); Brandon Scott Passmore, Fayetteville, AR (US)

(21) Appl. No.: 18/887,327

(22) Filed: Sep. 17, 2024

(51) Int. Cl. H01L 23/367; H01L 23/13; H01L 23/373; H01L 25/07

(52) U.S. Cl. CPC H10W 40/22; H10W 40/258; H10W 70/68; H10W 90/00

(57) ABSTRACT

Power semiconductor device assemblies are provided. In one example, a power semiconductor device assembly includes a semiconductor device package with one or more terminals. The semiconductor device package comprises one or more wide bandgap semiconductor die. The power semiconductor device assembly includes a support structure. The semiconductor device package is mounted onto the support structure. The power semiconductor device assembly includes an underfill structure. The underfill structure is at least partially on the support structure and the semiconductor device package.

### FIELD

Example aspects of the present disclosure relate generally to semiconductor devices.

### BACKGROUND

Semiconductor devices, including power semiconductor devices based on wide bandgap materials, may be formed on a semiconductor wafer as part of a semiconductor fabrication process. The semiconductor wafer may be diced into many individual pieces, each containing one or more semiconductor devices. Each of these pieces may be a semiconductor die. The semiconductor die may need to be attached to other components as part of packaging of the semiconductor device. For instance, a semiconductor die, such as a wide bandgap semiconductor die, may need to be attached to a conductive lead frame for use in a discrete power semiconductor device package or a power module. Materials used to attach the semiconductor die to other components may need to provide a thermal, mechanical, and/or electrical connection of the semiconductor die to the other components.

### SUMMARY

Aspects and advantages of embodiments of the present disclosure will be set forth in part in the following description, or can be learned from the description, or can be learned through practice of the embodiments.

In one aspect, the present disclosure provides an example power semiconductor device assembly. The assembly includes a semiconductor device package with one or more terminals, a support structure, and an attach layer between the semiconductor device package and the support structure. The semiconductor device package includes one or more wide bandgap semiconductor die. The semiconductor device package is on the support structure. The attach layer has a nonuniform thickness.

In one aspect, the present disclosure provides an example power semiconductor device assembly. The assembly includes a semiconductor device package with one or more terminals, a support structure, and an attach layer between the semiconductor device package and the support structure. The semiconductor device package includes one or more wide bandgap semiconductor die. The semiconductor device package is mounted onto the support structure. The attach layer has an average thickness of 200 μm or less. A maximum strain on the attach layer is 0.14 m/m or less.

In one aspect, the present disclosure provides an example power semiconductor device assembly. The assembly includes a semiconductor device package with one or more terminals, a support structure including a pedestal, and an attach layer between the semiconductor device package and a mounting surface of the pedestal. The semiconductor device package includes one or more wide bandgap semiconductor die. The semiconductor device package is mounted onto the support structure. The mounting surface of the pedestal is non-planar.

In one aspect, the present disclosure provides an example power semiconductor device assembly. The assembly includes a semiconductor device package with one or more terminals, a support structure, and an attach layer between the semiconductor device package and the support structure. The semiconductor device package includes one or more wide bandgap semiconductor die. The semiconductor device package is mounted onto the support structure. The support structure comprises a pedestal and a trench adjacent to an edge of the pedestal.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a cross-sectional view of an example power semiconductor device assembly as described in the present disclosure;

FIG. 2A depicts an example pedestal as described in the present disclosure;

FIG. 2B depicts a cross-sectional view of an example power semiconductor device assembly as described in the present disclosure;

FIG. 3A depicts an example pedestal as described in the present disclosure;

FIG. 3B depicts a cross-sectional view of an example power semiconductor device assembly as described in the present disclosure;

FIG. 4A depicts an example pedestal as described in the present disclosure;

FIG. 4B depicts a cross-sectional view of an example power semiconductor device assembly as described in the present disclosure;

FIG. 5A depicts an example pedestal as described in the present disclosure;

FIG. 5B depicts a cross-sectional view of an example power semiconductor device assembly as described in the present disclosure;

FIG. 6A depicts an example pedestal as described in the present disclosure;

FIG. 6B depicts a cross-sectional view of an example power semiconductor device assembly as described in the present disclosure;

FIG. 7A depicts an example pedestal as described in the present disclosure;

FIG. 7B depicts a cross-sectional view of an example power semiconductor device assembly as described in the present disclosure;

FIG. 8A depicts an example pedestal as described in the present disclosure;

FIG. 8B depicts a cross-sectional view of an example power semiconductor device assembly as described in the present disclosure;

FIG. 9A depicts an example pedestal as described in the present disclosure;

FIG. 9B depicts a cross-sectional view of an example power semiconductor device assembly as described in the present disclosure;

FIG. 10A depicts an example pedestal as described in the present disclosure;

FIG. 10B depicts a cross-sectional view of an example power semiconductor device assembly as described in the present disclosure;

FIG. 11A depicts an example pedestal as described in the present disclosure;

FIG. 11B depicts a cross-sectional view of an example power semiconductor device assembly as described in the present disclosure;

FIG. 12A depicts an example pedestal as described in the present disclosure;

FIG. 12B depicts a cross-sectional view of an example power semiconductor device assembly as described in the present disclosure;

FIG. 13A depicts an example pedestal as described in the present disclosure;

FIG. 13B depicts a cross-sectional view of an example power semiconductor device assembly as described in the present disclosure;

FIG. 14 depicts a cross-sectional view of an example power semiconductor device assembly as described in the present disclosure; and

FIG. 15 depicts a cross-sectional view of an example power semiconductor device assembly as described in the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to power semiconductor device assemblies including semiconductor device packages (e.g., discrete semiconductor device packages and power modules) mounted to support structures for use in semiconductor applications and other electronic applications. For example, the power semiconductor device assembly may include a semiconductor device package that is a power module. In some embodiments, semiconductor device packages may include one or more semiconductor die having at least one semiconductor device. The semiconductor die may include, for instance, wide bandgap semiconductor devices, such as silicon carbide-based semiconductor devices (e.g., MOSFETs, Schottky diodes) and Group III nitride-based semiconductor devices (e.g., high electron mobility transistor (HEMT) devices, etc.). The semiconductor die may include a substrate, such as a wide bandgap substrate, such as a silicon carbide substrate. The semiconductor die may include an epitaxial layer on the substrate, such as a wide bandgap epitaxial layer, such as silicon carbide epitaxial layer and/or a Group III-nitride epitaxial layer.

In some power semiconductor device packages, one or more semiconductor device packages may be mounted on a support structure (e.g., a heat sink) using an attach material such as, for example, sintered silver. More particularly, sintered silver (e.g., an attach material) may be deposited on the support structure, and the semiconductor device package may be placed on the attach material on the contact portion of the support structure. The attach material may be subjected to bonding or a bonding process (e.g., sintering) to secure the semiconductor device package to the attach material and support structure. The attach material also acts as a thermal conduit between the semiconductor package and the support structure.

As used herein, the term “bonding” or “bonding process” refers to causing a transition of a material from a first form to a second form. A bonding process may or may not require attaching a component to the material. Sintering, reflow, annealing, curing, exposing to light, exposing to ultraviolet light, and ultrasonic bonding are examples of bonding processes and are encompassed by the term “bonding” or “bonding process” in the disclosure and in the claims.

The various technologies that are practiced in the semiconductor industry for mounting semiconductor device packages to support structures present specific challenges and limitations. For instance, the semiconductor device package and support structure may experience forces causing the contact portion between the two to separate and break. In mounting methods that require additional components, the additional components may deteriorate over time due to forces exerted on the additional components. Additionally, the semiconductor device package may experience continuous heat cycling throughout operation which may cause cracking or separation of the semiconductor device package from the support structure.

Typically, the attach layer is a thin uniform layer that connects the two faces to be bonded. For example, one face may be a surface of the semiconductor device package, and the other face may be a pedestal making up a part of the support structure. Typically, the pedestal has a flat top surface and vertical edges meeting the top surface at a right angle. In this configuration, the stresses tend to get amplified at the edges of the attach layer. This manifests as a build-up of permanent deformation resulting from the excess plastic work. This accelerates failure by causing the bond layer to delaminate from the bonded surfaces, which can result in failure of the entire system. For example, these high stress and strain regions at the edges can act as crack initiation sites from which the cracks propagate inwards, resulting in delamination.

Example aspects of the present disclosure are directed to support structures and attach layers that provide a strong bond between semiconductor device packages and the support structures and are less susceptible to separation and cracking. In some embodiments, the attach layer has a nonuniform thickness. The nonuniform thickness of the attach layer may be created by modifying the pedestal, particularly in the edge regions of the pedestal. In some embodiments, for example, the pedestal has chamfered edges, which allows for added volume of the attach material around the edges. When more material is provided at the edges (i.e., the attach layer is thicker at the edges), the attach material is better suited to withstand the high stresses and strains at the edges. Similarly, in some embodiments, the edge regions of the pedestal can be modified with various edge profiles, for example, fillets, sigmoids, steps, ramps, notches, undercuts, and the like. In some embodiments, rather than modifying the entire edge region of the pedestal (or in addition to edge modifications), the corners are modified, such as by chamfering the corners of the pedestal.

In some embodiments, the support structure has a trench cut out of a base portion of the support structure and adjacent to the pedestal. The trench may be used to improve bonding strength/stress absorption alone or in combination with modifications to the pedestal, such as those mentioned above.

In some embodiments, rather than modifying the support structure to provide the attach layer with a portion of added volume (or in addition to such modifications), the semiconductor device package can be modified. For example, the surface of the semiconductor device package in contact with the attach layer (e.g., bottom surface) may be notched, such that the attach layer is thicker in the region of the notch.

The power semiconductor device assemblies described herein allow for relatively thin attach layers that are capable of reducing stress compared to uniform attach layers having a similar thickness. For example, the attach layer may have an average thickness of 200 μm or less, while the maximum strain on the attach layer is 0.14 m/m or less.

In some embodiments, the semiconductor device package may be on the pedestal of the support structure such that the semiconductor device package overhangs the pedestal. In some examples, the semiconductor device package does not overhang the pedestal. In some embodiments, the semiconductor device package may include one or more terminals. The one or more terminals may protrude laterally from the semiconductor device package and may be connected to one or more semiconductor die within the semiconductor device package. For example, the one or more terminals may be connected to one or more wide bandgap semiconductor die. In some embodiments, the support structure may be a heatsink. The heatsink may dissipate heat from the semiconductor device package mounted thereon.

Aspects of the present disclosure provide a number of technical effects and benefits. For instance, a nonuniform attach layer in accordance with example aspects of the present disclosure may reduce or prevent a semiconductor device package from separating or breaking off from a support structure. Additionally, some example aspects of the present disclosure may improve the thermo-mechanical fatigue resistance of the semiconductor device package, support structure, and/or attach material.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

A wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials, without deviating from the scope of the present disclosure. Example wide bandgap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

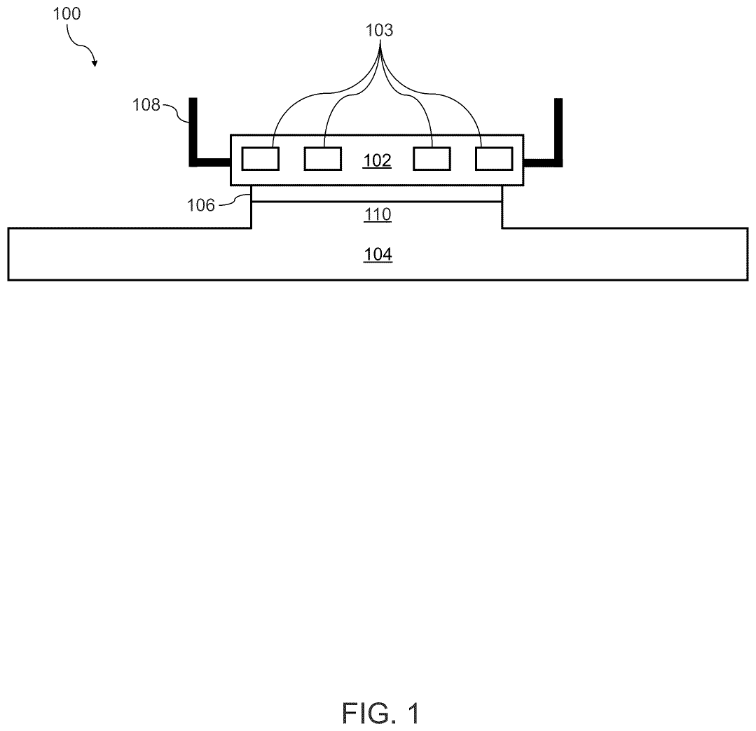

FIG. 1 depicts an example power semiconductor device assembly 100. The power semiconductor device assembly 100 may include a semiconductor device package 102 mounted on a support structure 104 using an attach layer 106. The semiconductor device package 102 may be mounted to the support structure 104. In some embodiments, the semiconductor device package 102 may include one or more terminals 108 that may protrude laterally from the semiconductor device package 102. Additionally, the semiconductor device package 102 may include one or more wide bandgap semiconductor die 103. In some embodiments, the power semiconductor device assembly may include an attach layer 106 such as, for example, sintered silver or another attach material. In some embodiments, the semiconductor device package 102 may be mounted on a pedestal 110 of the support structure 104. In some embodiments, the semiconductor device package 102 may overhang the pedestal 110 of the support structure 104.

The semiconductor device package 102 may include a variety of semiconductor die and devices. For instance, the semiconductor package 102 may include silicon-carbide based semiconductor die with one or more semiconductors devices such as a silicon carbide-based MOSFETs and/or silicon carbide-based Schottky diodes on the one or more wide bandgap semiconductor die 103. Additionally, or alternatively, the semiconductor device package 102 may include Group III nitride-based devices such as Group III nitride-based high electron mobility transistors (HEMTs) on the one or more wide bandgap semiconductor die 103. In some embodiments, the semiconductor device package 102 may be a power module. In some embodiments, the support structure 104 may be a heatsink that provides a cooling path thermal energy from the semiconductor device package 102.

In some embodiments, the attach layer has a non-uniform thickness. One method of forming a semiconductor device package assembly with an attach layer having a non-uniform thickness is to employ a pedestal having a non-planar mounting surface. As used herein, the mounting surface refers to the portion of the pedestal to which the attach layer is adhered to. In some embodiments, a peripheral portion (e.g., edge portion) of the pedestal may be modified. Modifications may include edge or corner profiles causing the thickness of the attach layer to be thicker in at least one part of a peripheral portion compared to a central portion. Such edge or corner profiles may include, for example, a chamfer, a bevel, a fillet, a sigmoid, a step, a notch, a ramp, an undercut, a trench, and the like, as will be discussed in more detail below.

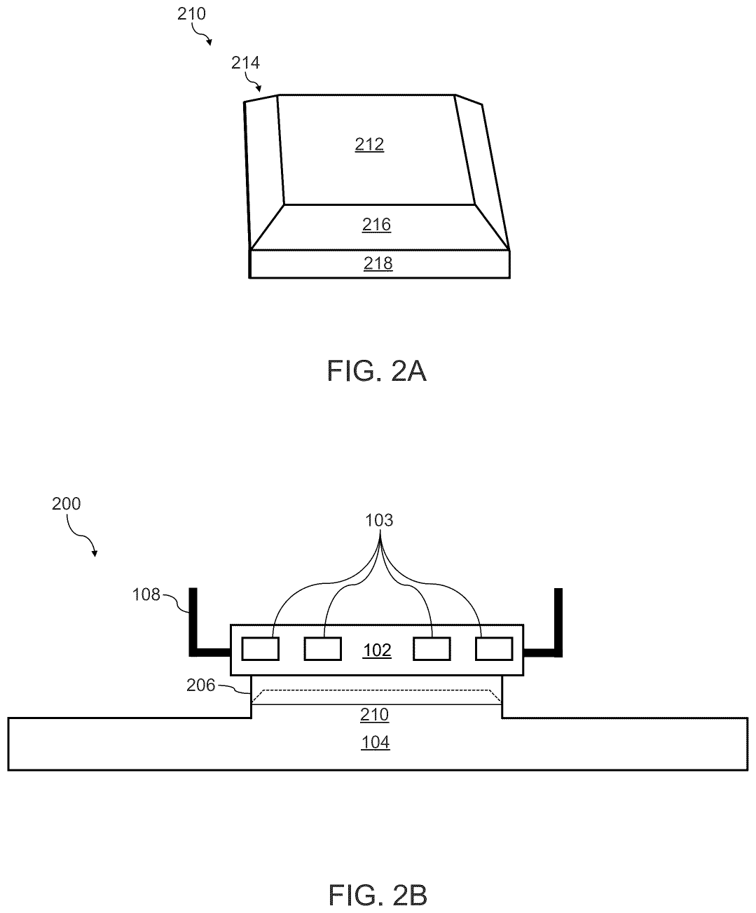

One example embodiment of a pedestal having a non-planar mounting surface is shown in FIG. 2A. The pedestal 210 comprises a central portion 212 and a peripheral portion 214. The peripheral portion 214 has chamfered edges, resulting in edges having perpendicular surfaces 218 and angled surfaces 216 relative to the flat top surface of the central portion 212.

FIG. 2B shows an example semiconductor device assembly 200 containing the pedestal 210. The semiconductor device package 102 is mounted on the support structure 104 using attach layer 206 which is adhered to the pedestal 210. The dashed line shows the portion of the pedestal 210 that is not visible from a side view of the semiconductor device package assembly. It can be seen that the attach layer 206 is thicker at its edges (i.e., in a peripheral portion) than at its center.

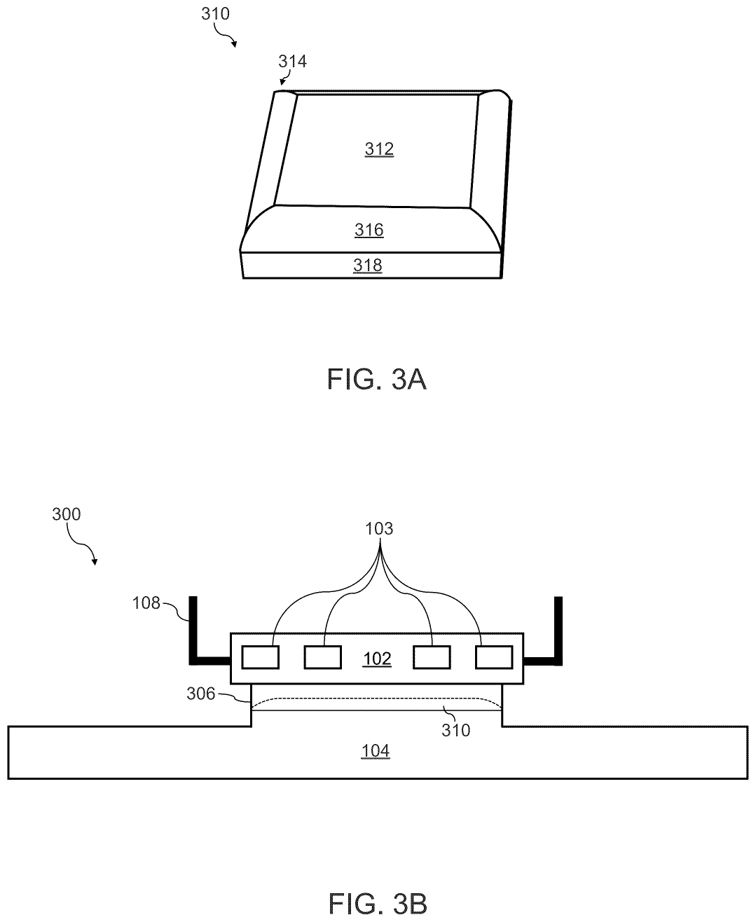

Another example embodiment of a pedestal having a non-planar mounting surface is shown in FIG. 3A. The pedestal 310 comprises a central portion 312 and a peripheral portion 314. The peripheral portion 314 has filleted edges, resulting in the edges having perpendicular surfaces 318 relative to the flat top surface of the central portion 312, and rounded surfaces 316.

FIG. 3B shows an example semiconductor device assembly 300 containing the pedestal 310. The semiconductor device package 102 is mounted on the support structure 104 using attach layer 306 which is adhered to the pedestal 310. The dashed line shows the portion of the pedestal 310 that is not visible from a side view of the semiconductor device package assembly. It can be seen that the attach layer 306 is thicker at its edges (i.e., in a peripheral portion) than at its center.

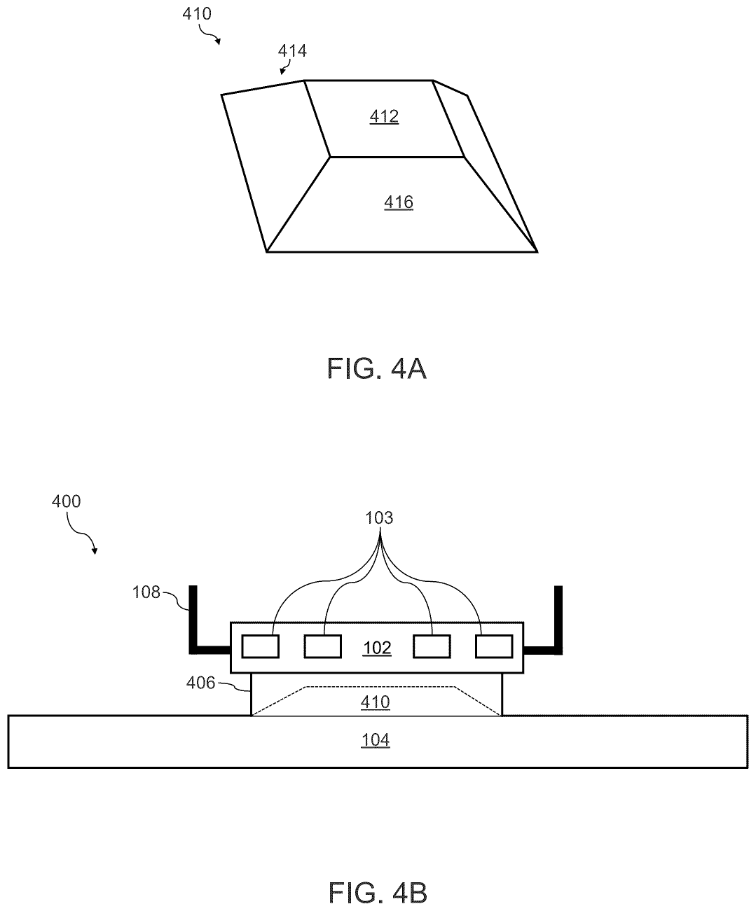

Another example embodiment of a pedestal having a non-planar mounting surface is shown in FIG. 4A. The pedestal 410 comprises a central portion 412 and a peripheral portion 414. The peripheral portion 414 has beveled edges, resulting in the edges having angled surfaces 416 relative to the flat top surface of the central portion 412. The beveled edge profile of pedestal 410 differs from the chamfered edge profile of pedestal 210 by not having edge surfaces perpendicular to the flat top surface of the central portion 412.

FIG. 4B shows an example semiconductor device assembly 400 containing the pedestal 410. The semiconductor device package 102 is mounted on the support structure 104 using attach layer 406 which is adhered to the pedestal 410. The dashed line shows the portion of the pedestal 410 that is not visible from a side view of the semiconductor device package assembly. It can be seen that the attach layer 406 is thicker at its edges (i.e., in a peripheral portion) than at its center.

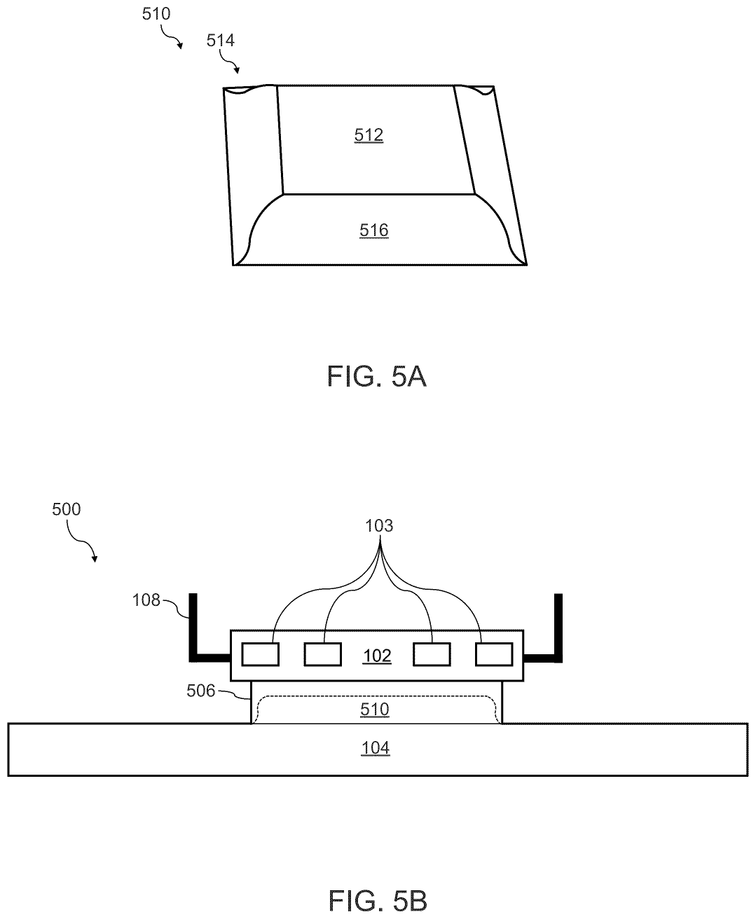

Another example embodiment of a pedestal having a non-planar mounting surface is shown in FIG. 5A. The pedestal 510 comprises a central portion 512 and a peripheral portion 514. The peripheral portion 514 has a sigmoid edge profile containing edges having sigmoidal (i.e., S-shaped) surfaces 516. For example, the edges have a convex upper shape and a concave lower shape. In other embodiments, the edges may have a concave upper shape and a convex lower shape.

FIG. 5B shows an example semiconductor device assembly 500 containing the pedestal 510. The semiconductor device package 102 is mounted on the support structure 104 using attach layer 506 which is adhered to the pedestal 510. The dashed line shows the portion of the pedestal 510 that is not visible from a side view of the semiconductor device package assembly. It can be seen that the attach layer 506 is thicker at its edges (i.e., in a peripheral portion) than at its center.

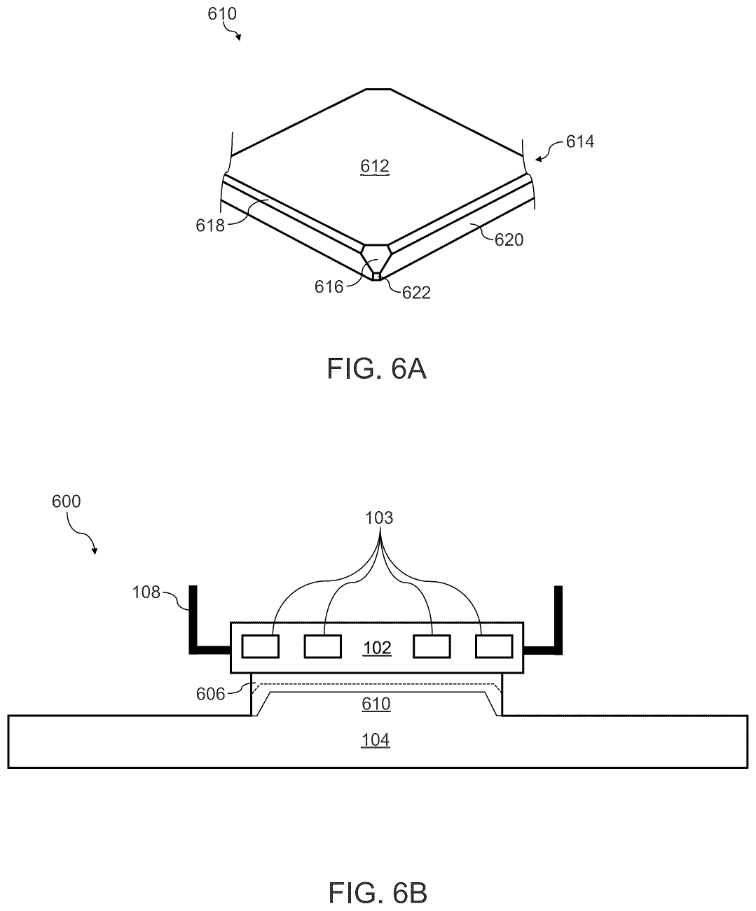

Another example embodiment of a pedestal having a non-planar mounting surface is shown in FIG. 6A. The pedestal 610 comprises a central portion 612 and a peripheral portion 614. The peripheral portion 614 has chamfered edges, resulting in the edges having perpendicular surfaces 620 and angled surfaces 618 relative to the flat top surface of the central portion 612. The pedestal 610 also contains chamfered corners, resulting in angled corner surfaces 616 which are angled with respect to the flat top surface of central portion 612 and the two adjacent perpendicular surfaces 620. The pedestal 610 also has chamfered vertical edges 622 which are perpendicular to the flat top surface of central portion 612 but angled relative to perpendicular surfaces 620. In other embodiments, the pedestal can have chamfered corners without having chamfered edges (e.g., 620 and/or 622).

FIG. 6B shows an example semiconductor device assembly 600 containing the pedestal 610. The semiconductor device package 102 is mounted on the support structure 104 using attach layer 606 which is adhered to the pedestal 610. The dashed line shows the portion of the pedestal 610 that is not visible from a side view of the semiconductor device package assembly. It can be seen that the attach layer 606 is thicker at its edges (i.e., in a peripheral portion) than at its center and is thickest in its corner areas.

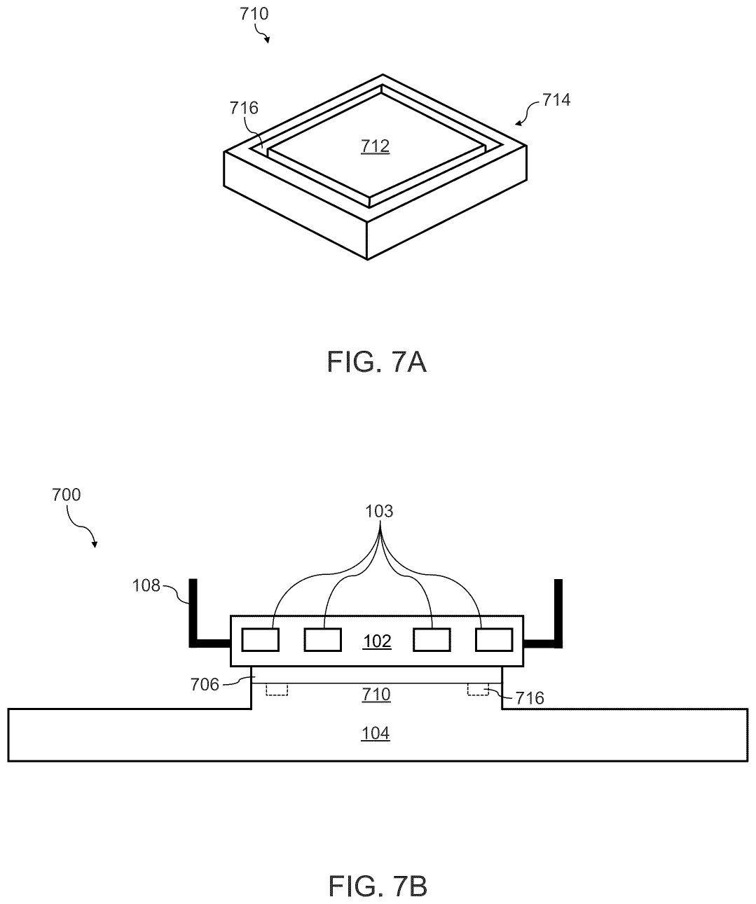

Another example embodiment of a pedestal having a non-planar mounting surface is shown in FIG. 7A. The pedestal 710 comprises a central portion 712 and a peripheral portion 714. The peripheral portion 714 has a notch 716 formed therein. As shown in FIGS. 7A and 7B, in some embodiments, the notch may have square corners. In other embodiments, notches may be U-shaped, V-shaped, etc.

FIG. 7B shows an example semiconductor device assembly 700 containing the pedestal 710. The semiconductor device package 102 is mounted on the support structure 104 using attach layer 706 which is adhered to the pedestal 710. The dashed line shows the portion of the pedestal 710 that is not visible from a side view of the semiconductor device package assembly. It can be seen that the attach layer 706 is thicker at the part of the peripheral portion that enters the notch 716 than at its center.

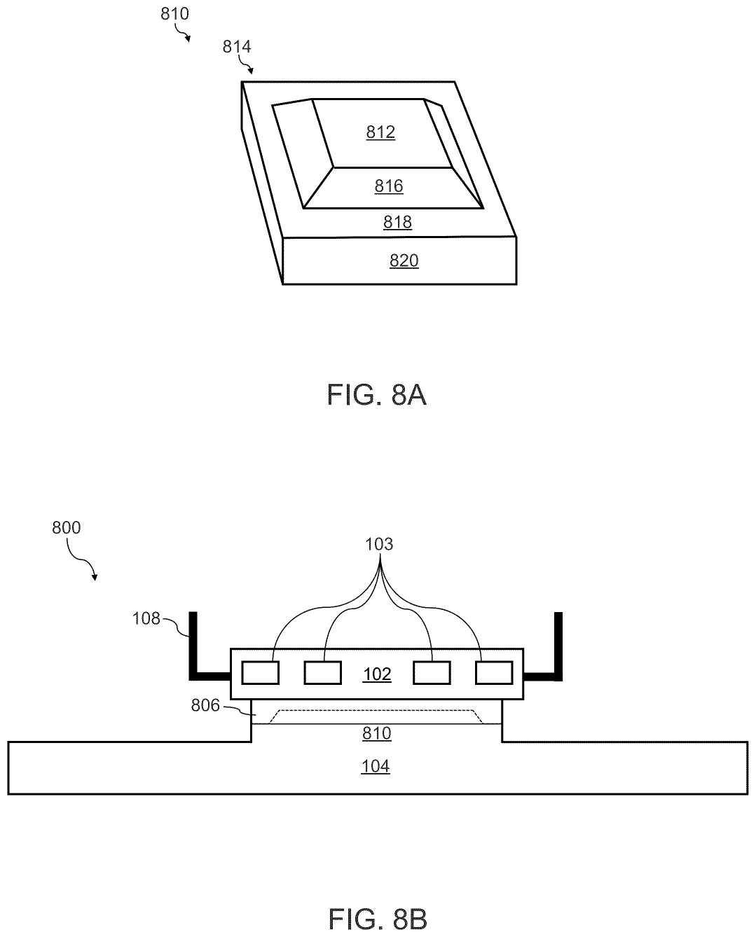

Another example embodiment of a pedestal having a non-planar mounting surface is shown in FIG. 8A. The pedestal 810 comprises a central portion 812 and a peripheral portion 814. The peripheral portion 814 comprises a step and a bevel, resulting in the edges having perpendicular surfaces 820, parallel step surfaces 818, and angled (i.e., ramped or beveled) surfaces 816 relative to the flat top surface of the central portion 812. In some embodiments, rather than having a step and a bevel, the pedestal may have a step without an adjacent bevel. In such embodiments, the pedestal contains two sets of perpendicular surfaces relative to the flat top surface of the central portion 812.

FIG. 8B shows an example semiconductor device assembly 800 containing the pedestal 810. The semiconductor device package 102 is mounted on the support structure 104 using attach layer 806 which is adhered to the pedestal 810. The dashed line shows the portion of the pedestal 810 that is not visible from a side view of the semiconductor device package assembly. It can be seen that the attach layer 806 is thicker at its edges (i.e., in a peripheral portion) than at its center.

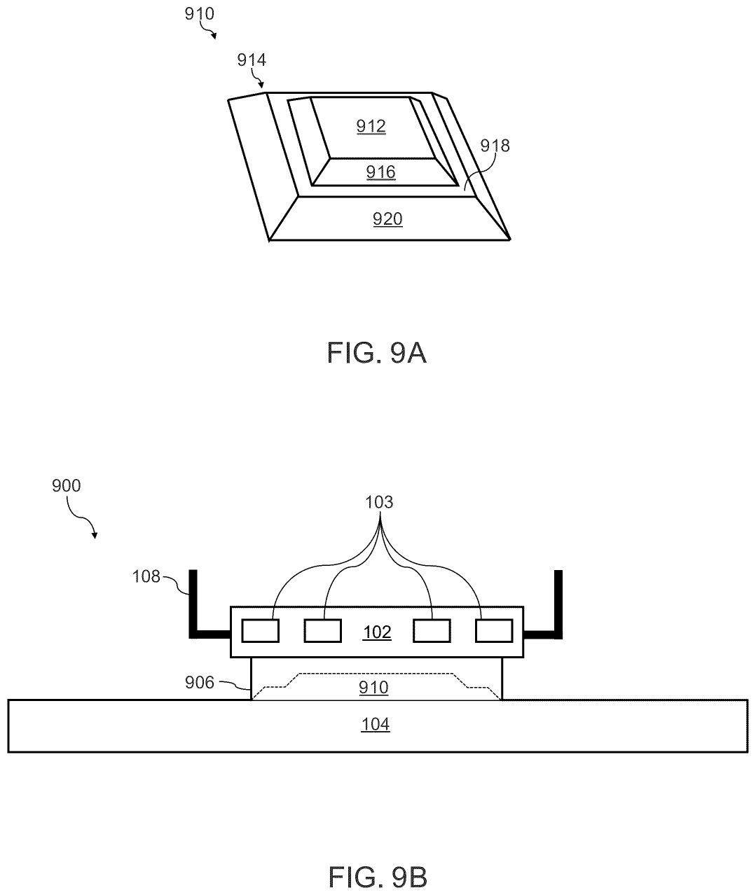

Another example embodiment of a pedestal having a non-planar mounting surface is shown in FIG. 9A. The pedestal 910 comprises a central portion 912 and a peripheral portion 914. The peripheral portion 914 comprises a lower beveled edge, a step, and an upper beveled edge, resulting in the edges having lower angled (i.e., ramped or beveled) surfaces 920, parallel step surfaces 918, and upper angled (i.e., ramped or beveled) surfaces 916 relative to the flat top surface of the central portion 912. In some embodiments, rather than having a step and an upper bevel, the pedestal may have a step without an adjacent upper bevel. In such embodiments, the pedestal contains lower beveled or ramped surfaces and an upper set of perpendicular surfaces relative to the flat top surface of the central portion 912.

FIG. 9B shows an example semiconductor device assembly 900 containing the pedestal 910. The semiconductor device package 102 is mounted on the support structure 104 using attach layer 906 which is adhered to the pedestal 910. The dashed line shows the portion of the pedestal 910 that is not visible from a side view of the semiconductor device package assembly. It can be seen that the attach layer 906 is thicker at its edges (i.e., in a peripheral portion) than at its center.

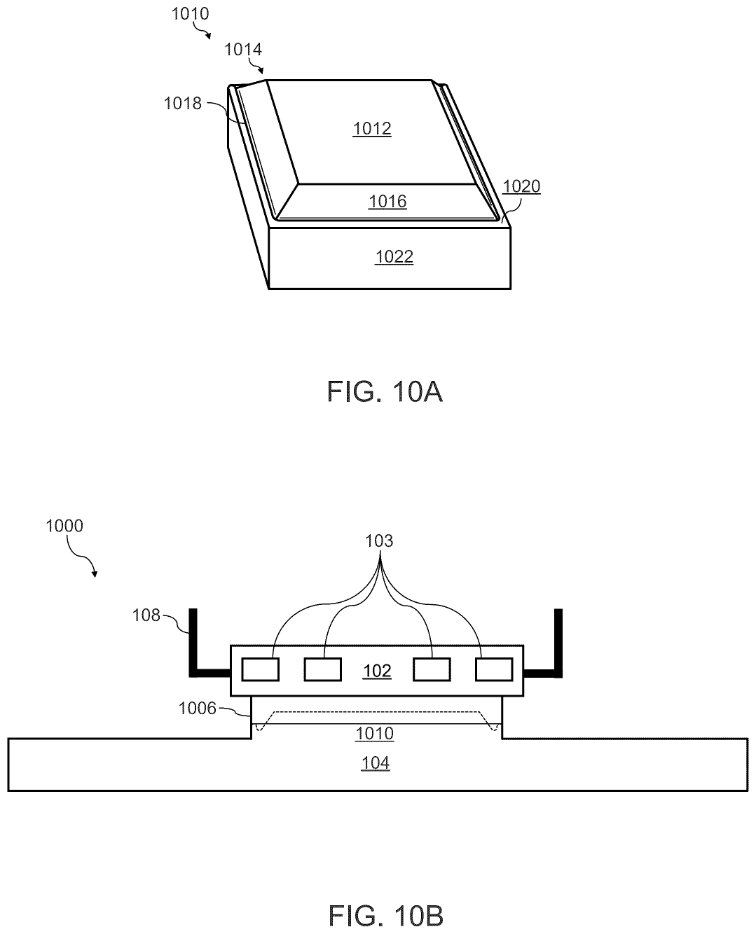

Another example embodiment of a pedestal having a non-planar mounting surface is shown in FIG. 10A. The pedestal 1010 comprises a central portion 1012 and a peripheral portion 1014. The peripheral portion 1014 comprises a step, a notch and a bevel, resulting in the edges having perpendicular surfaces 1022, parallel step surfaces 1020, notches 1018, and angled (i.e., ramped or beveled) surfaces 1016 relative to the flat top surface of the central portion 1012. In some embodiments, rather than having a bevel, the pedestal may have a notch without an adjacent bevel. In such embodiments, the pedestal contains lower and upper sets of perpendicular surfaces relative to the flat top surface of the central portion 1012 with a step and a notch between.

FIG. 10B shows an example semiconductor device assembly 1000 containing the pedestal 1010. The semiconductor device package 102 is mounted on the support structure 104 using attach layer 1006 which is adhered to the pedestal 1010. The dashed line shows the portion of the pedestal 1010 that is not visible from a side view of the semiconductor device package assembly. It can be seen that the attach layer 1006 is thicker at its edges (i.e., in a peripheral portion) than at its center and is thickest where it enters the notches in the pedestal.

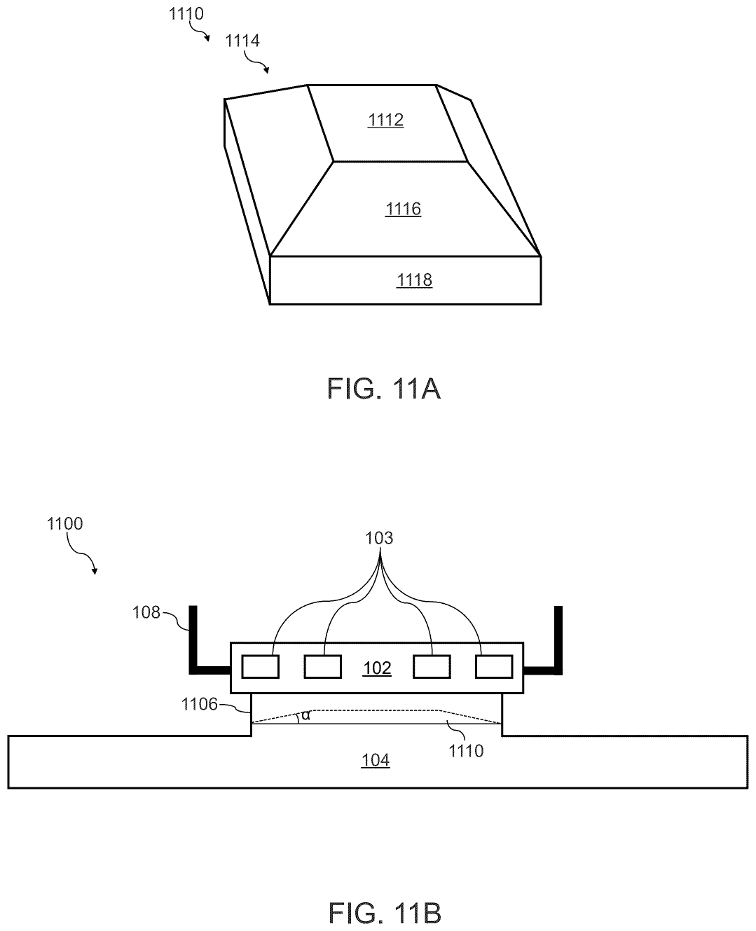

Another example embodiment of a pedestal having a non-planar mounting surface is shown in FIG. 11A. The pedestal 1110 comprises a central portion 1112 and a peripheral portion 1114. The peripheral portion 1114 has chamfered edges, resulting in the edges having perpendicular surfaces 1118 and angled surfaces 1116 relative to the flat top surface of the central portion 1112. The angle of the chamfer may be modified for an optimal combination of bond strength and material usage. For example, the angle α (shown in FIG. 11B) between the perpendicular surfaces 1118 and the angled surfaces 1116 may be from about 80° or less, such as about 70° or less, such as about 60° or less, such as about 50° or less, such as about 40° or less, such as about 30° or less, such as about 20° or less, and about 10° or more, such as about 20° or more, such as about 30° or more, such as about 40° or more, such as about 50° or more, such as about 60° or more, such as about 70° or more.

FIG. 11B shows an example semiconductor device assembly 1100 containing the pedestal 1110. The semiconductor device package 102 is mounted on the support structure 104 using attach layer 1106 which is adhered to the pedestal 1110. The dashed line shows the portion of the pedestal 1110 that is not visible from a side view of the semiconductor device package assembly. It can be seen that the attach layer 1106 is thicker at its edges (i.e., in a peripheral portion) than at its center. It can also be seen that angle α is smaller in the embodiment shown in FIGS. 11A and 11B compared to that of FIGS. 2A and 2B. As such, the angled surfaces (i.e., ramps) are longer in FIGS. 11A and 11B. For example, the length of the ramp may be from about 100 μm to about 400 μm, such as from about 150 μm to about 300 μm, such as from about 200 μm to about 250 μm.

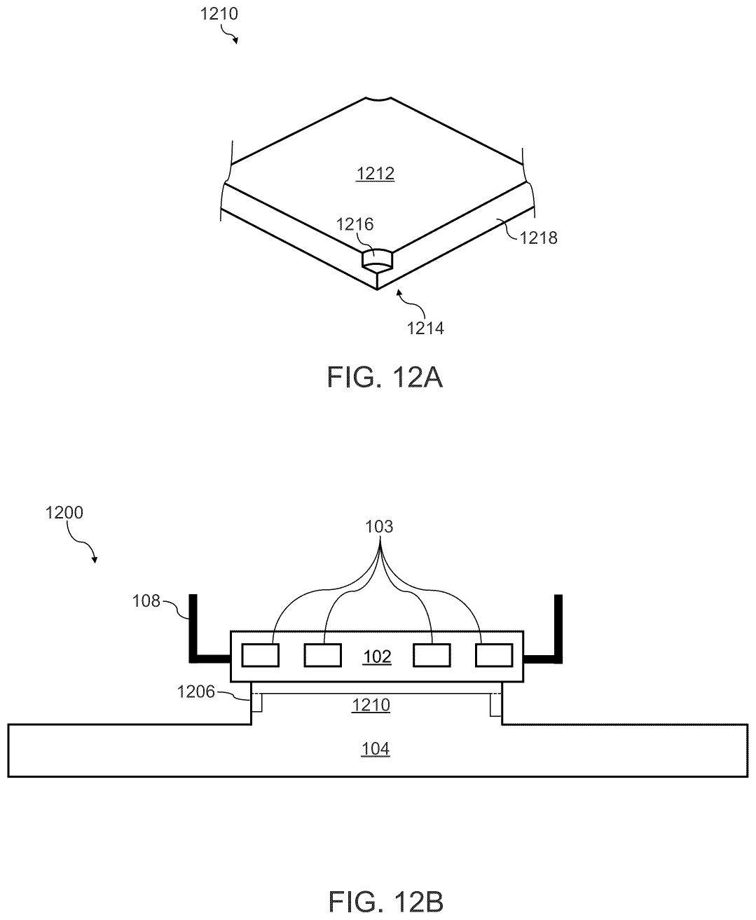

Another example embodiment of a pedestal having a non-planar mounting surface is shown in FIG. 12A. The pedestal 1210 comprises a central portion 1212 and a peripheral portion 1214. The peripheral portion 1214 has notched corners 1216. While the notched corners 1216 are curved in FIG. 12A, in other embodiments, they may be square or have any other suitable shape.

FIG. 12B shows an example semiconductor device assembly 1200 containing the pedestal 1210. The semiconductor device package 102 is mounted on the support structure 104 using attach layer 1206 which is adhered to the pedestal 1210. The dashed line shows the portion of the pedestal 1210 that is set back from a side view of the semiconductor device package assembly. It can be seen that the attach layer 1206 is thicker at its corners (i.e., in a peripheral portion) than at its center.

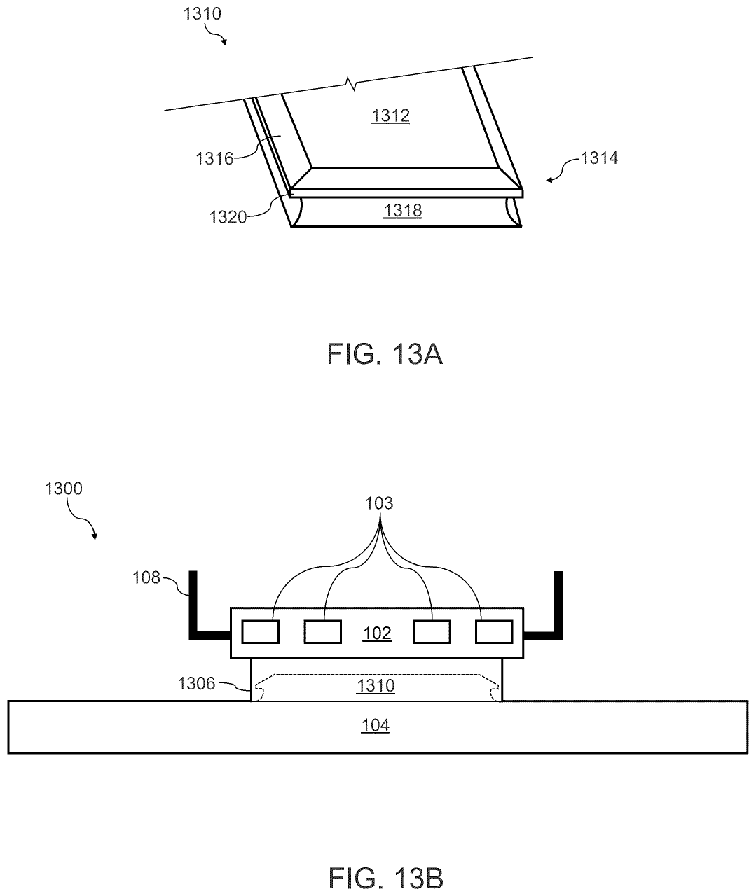

Another example embodiment of a pedestal having a non-planar mounting surface is shown in FIG. 13A. The pedestal 1310 comprises a central portion 1312 and a peripheral portion 1314. The peripheral portion 1314 comprises an undercut edge and a chamfer, resulting in the edges having concave surfaces 1318, perpendicular surfaces 1320, and angled (i.e., ramped) surfaces 1316 relative to the flat top surface of the central portion 1312. In some embodiments, the pedestal may have an undercut without a ramped or chamfered edge. In some embodiments, the undercut may be rounded as in FIG. 13A. In other embodiments, the undercut may be square or have any other suitable profile. The undercut may result in the formation of a ledge under which the attach layer can penetrate.

FIG. 13B shows an example semiconductor device assembly 1300 containing the pedestal 1310. The semiconductor device package 102 is mounted on the support structure 104 using attach layer 1306 which is adhered to the pedestal 1310. The dashed line shows the portion of the pedestal 1310 that is not visible from a side view of the semiconductor device package assembly. It can be seen that the attach layer 1306 is thicker at its edges (i.e., in a peripheral portion) than at its center and “locks on” to the ledges of the pedestal 1310 formed above the undercut portions.

While the pedestals illustrated herein are modified on all 4 edges and/or corners, it should be understood that the pedestal may only be modified in certain areas. For example, in some embodiments, on pedestals having a rectangular shape, only one of the edges or corners may be modified. In other embodiments, two of the edges or corners may be modified. The two modified edges or corners may be opposite or adjacent to each other. In other embodiments, three of the edges or corners may be modified. Further, while the pedestals illustrated herein are shown having rectangular shapes, it should be understood that the pedestal can have any shape suitable for mounting a semiconductor device package thereon. For example, the pedestal may be round (e.g., circular or ovular), triangular, quadrangular, pentagonal, or the like.

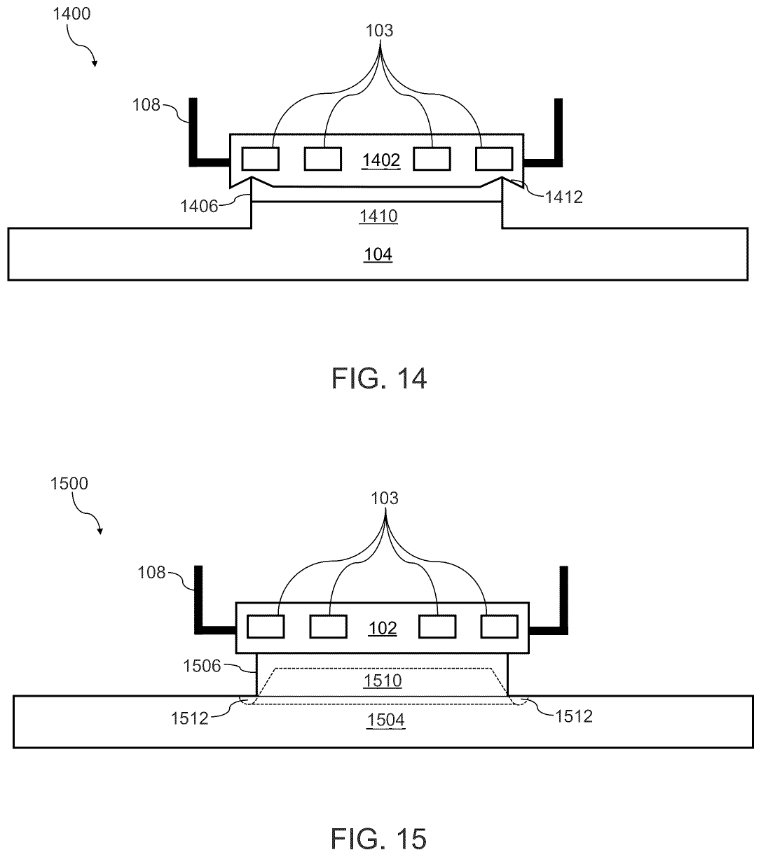

In some embodiments, to achieve a non-uniform thickness in the attach layer, a surface of the semiconductor device package can be modified. For example, FIG. 14 shows a semiconductor device package assembly 1400 containing a pedestal 1410 having a planar mounting surface, a semiconductor device package 1402 having notches 1412 on a bottom surface thereof, and an attach layer 1406 therebetween. The attach layer 1406 is thicker at its edges (i.e., in a peripheral portion) than at its center, as a portion of the attach layer enters the notches 1412.

In some embodiments, to achieve a non-uniform thickness in the attach layer, a trench can be formed in the support structure surrounding the pedestal. For example, FIG. 15 shows a semiconductor device package assembly 1500 containing a support structure 1504 having a pedestal 1510 with beveled edges, a semiconductor device package 102, and an attach layer 1506 therebetween. The attach layer 1506 is thicker at its edges (i.e., in a peripheral portion) than at its center due to both the beveled edges of the pedestal 1510 and the trenches 1512. For example, a portion of the attach layer may enter the trenches 1512 to further increase its thickness at the edges and provide improved bond strength. While the semiconductor device package assembly 1500 contains a pedestal with beveled edges, in other embodiments, a trench can be used in conjunction with any of the other pedestals described herein, or any other suitable pedestals. In some embodiments, for example, the pedestal may have a flat top surface (e.g., as shown in FIG. 1) with a trench surrounding at least a portion of the pedestal.

The semiconductor device package assemblies described herein can have lower strain at the attach layer compared to similar assemblies having a uniform attach layer with a similar average thickness. For example, the ratio of maximum strain of a semiconductor device package assembly having an attach layer with a non-uniform thickness as described herein to the maximum strain of a similar semiconductor device package assembly having a uniform attach layer of the same average thickness may be less than 1, such as about 0.9 or less, such as about 0.8 or less, such as about 0.7 or less, such as about 0.6 or less, such as about 0.55 or less, such as about 0.5 or less, such as about 0.45 or less. The ratio may be about 0.1 or more, such as about 0.2 or more, such as about 0.3 or more, such as about 0.4 or more. Similarly, a semiconductor device package assembly as described herein may have a maximum strain on the attach layer of about 0.14 m/m or less, such as about 0.12 m/m or less, such as about 0.1 m/m or less, such as about 0.09 m/m or less, such as about 0.08 m/m or less, such as about 0.07 m/m or less, such as about 0.06 m/m or less, even when the average thickness of the attach layer is 200 μm or less, such as about 150 μm. The maximum strain is typically more than 0.01 m/m, such as about 0.2 m/m or more, such as about 0.3 m/m or more, such as about 0.4 m/m or more, such as about 0.5 m/m or more.

The attach layer may have an average thickness of about 1 mm or less, such as about 800 μm or less, such as about 500 μm or less, such as about 300 μm or less, such as about 200 μm or less, such as about 150 μm or less. The attach layer may have an average thickness of about 50 μm or more, such as about 80 μm or more, such as about 100 μm or more, such as about 150 μm or more.

Example aspects of the present disclosure are set forth below. Any of the below features or examples may be used in combination with any of the embodiments or features provided in the present disclosure.

In one aspect, the present disclosure provides an example power semiconductor device assembly. The assembly includes a semiconductor device package with one or more terminals, a support structure, and an attach layer between the semiconductor device package and the support structure. The semiconductor device package includes one or more wide bandgap semiconductor die. The semiconductor device package is on the support structure. The attach layer has a nonuniform thickness.

In some implementations of the example power semiconductor device assembly, the attach layer has a first portion and a second portion, wherein a thickness of the first portion is greater than a thickness of the second portion.

In some implementations of the example power semiconductor device assembly, the first portion is in a peripheral portion of the attach layer and the second portion is in a central portion of the attach layer.

In some implementations of the example power semiconductor device assembly, the attach layer has a rectangular shape having a central portion and four corner areas and the first portion is at least one of the corner areas and the second portion is in the central portion.

In some implementations of the example power semiconductor device assembly, a peripheral portion of the attach layer has a non-uniform thickness and a central portion of the attach layer has a uniform thickness.

In some implementations of the example power semiconductor device assembly, the attach layer includes sintered silver.

In some implementations of the example power semiconductor device assembly, the support structure is a heatsink.

In some implementations of the example power semiconductor device assembly, the support structure includes a pedestal and the attach layer is in contact with the pedestal.

In some implementations of the example power semiconductor device assembly, the semiconductor device package overhangs the pedestal.

In some implementations of the example power semiconductor device assembly, the semiconductor device package does not overhang the pedestal.

In some implementations of the example power semiconductor device assembly, the pedestal has a non-planar mounting surface.

In some implementations of the example power semiconductor device assembly, the pedestal has a chamfered edge.

In some implementations of the example power semiconductor device assembly, an angle between a base of the support structure and the chamfered edge is from about 10 degrees to about 80 degrees.

In some implementations of the example power semiconductor device assembly, the pedestal has a filleted edge.

In some implementations of the example power semiconductor device assembly, the pedestal has a chamfered corner.

In some implementations of the example power semiconductor device assembly, the pedestal has a sigmoid edge profile.

In some implementations of the example power semiconductor device assembly, the pedestal includes at least one step.

In some implementations of the example power semiconductor device assembly, the pedestal has a notch on the mounting surface.

In some implementations of the example power semiconductor device assembly, the pedestal has a ramped surface adjacent to the notch.

In some implementations of the example power semiconductor device assembly, the pedestal has a ramped surface adjacent to an edge portion.

In some implementations of the example power semiconductor device assembly, the ramped surface has a length of at least about 150 μm.

In some implementations of the example power semiconductor device assembly, the pedestal has at least one modified corner.

In some implementations of the example power semiconductor device assembly, the pedestal has an undercut edge.

In some implementations of the example power semiconductor device assembly, the pedestal has a ramped surface adjacent to the undercut edge.

In some implementations of the example power semiconductor device assembly, the support structure includes a trench adjacent to an edge of the pedestal.

In some implementations of the example power semiconductor device assembly, the semiconductor device package has a notched bottom surface.

In some implementations of the example power semiconductor device assembly, the one or more terminals protrude laterally from the semiconductor device package and are connected to the one or more wide bandgap semiconductor die.

In some implementations of the example power semiconductor device assembly, the one or more wide bandgap semiconductor die comprise silicon carbide.

In some implementations of the example power semiconductor device assembly, the semiconductor device package includes a silicon carbide-based MOSFET.

In some implementations of the example power semiconductor device assembly, the semiconductor device package includes a silicon carbide-based Schottky diode.

In some implementations of the example power semiconductor device assembly, the one or more wide bandgap semiconductor die comprise a Group III-nitride.

In some implementations of the example power semiconductor device assembly, the semiconductor device package includes a Group III nitride-based high electron mobility transistor.

In some implementations of the example power semiconductor device assembly, the semiconductor device package is a power module.

In one aspect, the present disclosure provides an example power semiconductor device assembly. The assembly includes a semiconductor device package with one or more terminals, a support structure, and an attach layer between the semiconductor device package and the support structure. The semiconductor device package includes one or more wide bandgap semiconductor die. The semiconductor device package is mounted onto the support structure. The attach layer has an average thickness of 200 μm or less. A maximum strain on the attach layer is 0.14 m/m or less.

In some implementations of the example power semiconductor device assembly, the attach layer has a first portion and a second portion, wherein a thickness of the first portion is greater than a thickness of the second portion.

In some implementations of the example power semiconductor device assembly, the first portion is in a peripheral portion of the attach layer and the second portion is in a central portion of the attach layer.

In some implementations of the example power semiconductor device assembly, the attach layer has a rectangular shape having a central portion and four corner areas and the first portion is at least one of the corner areas and the second portion is in the central portion.

In some implementations of the example power semiconductor device assembly, the attach layer includes sintered silver.

In some implementations of the example power semiconductor device assembly, the support structure is a heatsink.

In some implementations of the example power semiconductor device assembly, the support structure includes a pedestal and the attach layer is in contact with the pedestal.

In some implementations of the example power semiconductor device assembly, the semiconductor device package overhangs the pedestal.

In some implementations of the example power semiconductor device assembly, the semiconductor device package does not overhang the pedestal.

In some implementations of the example power semiconductor device assembly, the pedestal has a non-planar mounting surface.

In some implementations of the example power semiconductor device assembly, the pedestal has a chamfered edge.

In some implementations of the example power semiconductor device assembly, an angle between a base of the support structure and the chamfered edge is from about 10 degrees to about 80 degrees.

In some implementations of the example power semiconductor device assembly, the pedestal has a filleted edge.

In some implementations of the example power semiconductor device assembly, the pedestal has a chamfered corner.

In some implementations of the example power semiconductor device assembly, the pedestal has a sigmoid edge profile.

In some implementations of the example power semiconductor device assembly, the pedestal includes at least one step.

In some implementations of the example power semiconductor device assembly, the pedestal has a notch on its mounting surface.

In some implementations of the example power semiconductor device assembly, the pedestal has a ramped surface adjacent to the notch.

In some implementations of the example power semiconductor device assembly, the pedestal has a ramped surface adjacent to an edge portion.

In some implementations of the example power semiconductor device assembly, the ramped surface has a length of at least about 150 μm.

In some implementations of the example power semiconductor device assembly, the pedestal has at least one modified corner.

In some implementations of the example power semiconductor device assembly, the pedestal has an undercut edge.

In some implementations of the example power semiconductor device assembly, the pedestal has a ramped surface adjacent to the undercut edge.

In some implementations of the example power semiconductor device assembly, the support structure includes a trench adjacent to an edge of the pedestal.

In some implementations of the example power semiconductor device assembly, the semiconductor device package has a notched bottom surface.

In some implementations of the example power semiconductor device assembly, the one or more terminals protrude laterally from the semiconductor device package and are connected to the one or more wide bandgap semiconductor die.

In some implementations of the example power semiconductor device assembly, the one or more wide bandgap semiconductor die comprise silicon carbide.

In some implementations of the example power semiconductor device assembly, the semiconductor device package includes a silicon carbide-based MOSFET.

In some implementations of the example power semiconductor device assembly, the semiconductor device package includes a silicon carbide-based Schottky diode.

In some implementations of the example power semiconductor device assembly, the one or more wide bandgap semiconductor die comprise a Group III-nitride.

In some implementations of the example power semiconductor device assembly, the semiconductor device package includes a Group III nitride-based high electron mobility transistor.

In some implementations of the example power semiconductor device assembly, the semiconductor device package is a power module.

In one aspect, the present disclosure provides an example power semiconductor device assembly. The assembly includes a semiconductor device package with one or more terminals, a support structure including a pedestal, and an attach layer between the semiconductor device package and a mounting surface of the pedestal. The semiconductor device package includes one or more wide bandgap semiconductor die. The semiconductor device package is mounted onto the support structure. The mounting surface of the pedestal is non-planar.

In some implementations of the example power semiconductor device assembly, the attach layer has a first portion and a second portion, wherein a thickness of the first portion is greater than a thickness of the second portion.

In some implementations of the example power semiconductor device assembly, the first portion is in a peripheral portion of the attach layer and the second portion is in a central portion of the attach layer.

In some implementations of the example power semiconductor device assembly, the attach layer has a rectangular shape having a central portion and four corner areas and the first portion is at least one of the corner areas and the second portion is in the central portion.

In some implementations of the example power semiconductor device assembly, the attach layer includes sintered silver.

In some implementations of the example power semiconductor device assembly, the support structure is a heatsink.

In some implementations of the example power semiconductor device assembly, the semiconductor device package overhangs the pedestal.

In some implementations of the example power semiconductor device assembly, the semiconductor device package does not overhang the pedestal.

In some implementations of the example power semiconductor device assembly, the pedestal has a chamfered edge.

In some implementations of the example power semiconductor device assembly, an angle between a base of the support structure and the chamfered edge is from about 10 degrees to about 80 degrees.

In some implementations of the example power semiconductor device assembly, the pedestal has a filleted edge.

In some implementations of the example power semiconductor device assembly, the pedestal has a chamfered corner.

In some implementations of the example power semiconductor device assembly, the pedestal has a sigmoid edge profile.

In some implementations of the example power semiconductor device assembly, the pedestal includes at least one step.

In some implementations of the example power semiconductor device assembly, the pedestal has a notch on mounting surface.

In some implementations of the example power semiconductor device assembly, the pedestal has a ramped surface adjacent to the notch.

In some implementations of the example power semiconductor device assembly, the pedestal has a ramped surface adjacent to an edge portion.

In some implementations of the example power semiconductor device assembly, the ramped surface has a length of at least about 250 μm.

In some implementations of the example power semiconductor device assembly, the pedestal has at least one modified corner.

In some implementations of the example power semiconductor device assembly, the pedestal has an undercut edge.

In some implementations of the example power semiconductor device assembly, the pedestal has a ramped surface adjacent to the undercut edge.

In some implementations of the example power semiconductor device assembly, the support structure includes a trench adjacent to an edge of the pedestal.

In some implementations of the example power semiconductor device assembly, the semiconductor device package has a notched bottom surface.

In some implementations of the example power semiconductor device assembly, the one or more terminals protrude laterally from the semiconductor device package and are connected to the one or more wide bandgap semiconductor die.

In some implementations of the example power semiconductor device assembly, the one or more wide bandgap semiconductor die comprise silicon carbide.

In some implementations of the example power semiconductor device assembly, the semiconductor device package includes a silicon carbide-based MOSFET.

In some implementations of the example power semiconductor device assembly, the semiconductor device package includes a silicon carbide-based Schottky diode.

In some implementations of the example power semiconductor device assembly, the one or more wide bandgap semiconductor die comprise a Group III-nitride.

In some implementations of the example power semiconductor device assembly, the semiconductor device package includes a Group III nitride-based high electron mobility transistor.

In some implementations of the example power semiconductor device assembly, the semiconductor device package is a power module.

In one aspect, the present disclosure provides an example power semiconductor device assembly. The assembly includes a semiconductor device package with one or more terminals, a support structure, and an attach layer between the semiconductor device package and the support structure. The semiconductor device package includes one or more wide bandgap semiconductor die. The semiconductor device package is mounted onto the support structure. The support structure comprises a pedestal and a trench adjacent to an edge of the pedestal.

In some implementations of the example power semiconductor device assembly, the attach layer has a first portion and a second portion, wherein a thickness of the first portion is greater than a thickness of the second portion.

In some implementations of the example power semiconductor device assembly, the first portion is in a peripheral portion of the attach layer and the second portion is in a central portion of the attach layer.

In some implementations of the example power semiconductor device assembly, the attach layer has a rectangular shape having a central portion and four corner areas and the first portion is at least one of the corner areas and the second portion is in the central portion.

In some implementations of the example power semiconductor device assembly, the attach layer includes sintered silver.

In some implementations of the example power semiconductor device assembly, the support structure is a heatsink.

In some implementations of the example power semiconductor device assembly, the attach layer is in contact with the pedestal.

In some implementations of the example power semiconductor device assembly, the semiconductor device package overhangs the pedestal.

In some implementations of the example power semiconductor device assembly, the semiconductor device package does not overhang the pedestal.

In some implementations of the example power semiconductor device assembly, the pedestal has a non-planar mounting surface.

In some implementations of the example power semiconductor device assembly, the pedestal has a chamfered edge.

In some implementations of the example power semiconductor device assembly, an angle between a base of the support structure and the chamfered edge is from about 10 degrees to about 80 degrees.

In some implementations of the example power semiconductor device assembly, the pedestal has a filleted edge.

In some implementations of the example power semiconductor device assembly, the pedestal has a chamfered corner.

In some implementations of the example power semiconductor device assembly, the pedestal has a sigmoid edge profile.

In some implementations of the example power semiconductor device assembly, the pedestal includes at least one step.

In some implementations of the example power semiconductor device assembly, the pedestal has a notch on a mounting surface of the pedestal.

In some implementations of the example power semiconductor device assembly, the pedestal has a ramped surface adjacent to the notch.

In some implementations of the example power semiconductor device assembly, the pedestal has a ramped surface adjacent to an edge portion.

In some implementations of the example power semiconductor device assembly, the ramped surface has a length of at least about 150 μm.

In some implementations of the example power semiconductor device assembly, the pedestal has at least one modified corner.

In some implementations of the example power semiconductor device assembly, the pedestal has an undercut edge.

In some implementations of the example power semiconductor device assembly, the pedestal has a ramped surface adjacent to the undercut edge.

In some implementations of the example power semiconductor device assembly, the semiconductor device package has a notched bottom surface.

In some implementations of the example power semiconductor device assembly, the one or more terminals protrude laterally from the semiconductor device package and are connected to the one or more wide bandgap semiconductor die.

In some implementations of the example power semiconductor device assembly, the one or more wide bandgap semiconductor die comprise silicon carbide.

In some implementations of the example power semiconductor device assembly, the semiconductor device package includes a silicon carbide-based MOSFET.

In some implementations of the example power semiconductor device assembly, the semiconductor device package includes a silicon carbide-based Schottky diode.

In some implementations of the example power semiconductor device assembly, the one or more wide bandgap semiconductor die comprise a Group III-nitride.

In some implementations of the example power semiconductor device assembly, the semiconductor device package includes a Group III nitride-based high electron mobility transistor.

In some implementations of the example power semiconductor device assembly, the semiconductor device package is a power module.

### Example

Various semiconductor device package assemblies were formed having different pedestal shapes with attach layers of about the same average thickness, as described below. Each assembly was measured for its maximum strain on the attach layer. The results are shown in the Table below.

Sample 1 contained a pedestal having a chamfered edge, as shown in FIG. 2A.

Sample 2 contained a pedestal having a filleted edge, as shown in FIG. 3A.

Sample 3 contained a pedestal having a sigmoid edge, as shown in FIG. 5A.

Sample 4 contained a pedestal having a beveled edge and a bottom trench, as shown in FIG. 15.

Sample 5 contained a pedestal having a corner chamfer, as shown in FIG. 6A.

Sample 6 contained a pedestal having a flat pedestal (uniform attach layer) as shown in FIG. 1.

| Sample | Maximum strain |
|---|---|
| 1 | 0.073 |
| 2 | 0.078 |
| 3 | 0.078 |
| 4 | 0.073 |
| 5 | 0.089 |
| 6 | 0.160 |

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A power semiconductor device assembly comprising:
a semiconductor device package with one or more terminals, wherein the semiconductor device package comprises one or more wide bandgap semiconductor die;
a support structure, wherein the semiconductor device package is on the support structure; and
an attach layer between the semiconductor device package and the support structure, wherein the attach layer has a nonuniform thickness.

2. The power semiconductor device assembly of claim 1, wherein the attach layer has a first portion and a second portion, wherein a thickness of the first portion is greater than a thickness of the second portion.

3. The power semiconductor device assembly of claim 2, wherein the first portion is in a peripheral portion of the attach layer and the second portion is in a central portion of the attach layer.

4. The power semiconductor device assembly of claim 2, wherein the attach layer has a rectangular shape having a central portion and four corner areas and the first portion is at least one of the corner areas and the second portion is in the central portion.

5. The power semiconductor device assembly of claim 1, wherein a peripheral portion of the attach layer has a non-uniform thickness and a central portion of the attach layer has a uniform thickness.

6. The power semiconductor device assembly of claim 1, wherein the attach layer comprises sintered silver.

7. The power semiconductor device assembly of claim 1, wherein the support structure is a heatsink.

8. The power semiconductor device assembly of claim 1, wherein the support structure comprises a pedestal and the attach layer is in contact with the pedestal.

9. The power semiconductor device assembly of claim 8, wherein the pedestal has a non-planar mounting surface.

10. The power semiconductor device assembly of claim 9, wherein the pedestal has a chamfered edge, a filleted edge, a chamfered corner, or a sigmoid edge profile.

11. The power semiconductor device assembly of claim 9, wherein the pedestal comprises at least one step.

12. The power semiconductor device assembly of claim 9, wherein the pedestal has a notch on the mounting surface.

13. The power semiconductor device assembly of claim 9, wherein the pedestal has a ramped surface adjacent to an edge portion.

14. The power semiconductor device assembly of claim 9, wherein the pedestal has at least one modified corner.

15. The power semiconductor device assembly of claim 9, wherein the pedestal has an undercut edge.

16. The power semiconductor device assembly of claim 8, wherein the support structure comprises a trench adjacent to an edge of the pedestal.

17. The power semiconductor device assembly of claim 1, wherein the semiconductor device package has a notched bottom surface.

18. The power semiconductor device assembly of claim 1, wherein the one or more wide bandgap semiconductor die comprise silicon carbide.

19. A power semiconductor device assembly comprising:
a semiconductor device package with one or more terminals, wherein the semiconductor device package comprises one or more wide bandgap semiconductor die;
a support structure, wherein the semiconductor device package is mounted onto the support structure; and
an attach layer between the semiconductor device package and the support structure, wherein the attach layer has an average thickness of 200 μm or less, and wherein a maximum strain on the attach layer is 0.14 m/m or less.

20. A power semiconductor device assembly comprising:
a semiconductor device package with one or more terminals, wherein the semiconductor device package comprises one or more wide bandgap semiconductor die;
a support structure comprising a pedestal, wherein the semiconductor device package is mounted onto the support structure; and
an attach layer between the semiconductor device package and a mounting surface of the pedestal, wherein the mounting surface of the pedestal is non-planar.
